(19) United States
(12) Patent Application Publication
(10) Pub. No.: US 2002/0158296 A1
(43) Pub. Date: Oct. 31, 2002

(54) Solid imaging device and method of fabricating the same

(75) Inventor: Young Jun Kim, Suwon-shi (KR)

Correspondence Address: LADAS & PARRY, 26 WEST 61ST STREET, NEW YORK, NY, 10023, US

(73) Assignee: SAMSUNG ELECTRO-MECHANICS CO., LTD

(21) Appl. No.: 09/844,142

(22) Filed: Apr. 27, 2001

(51) Int. Cl. H01L 21/00; H01L 33/00

(52) U.S. Cl. 257/432; 257/91; 257/95; 257/433; 257/434; 257/98

(57) ABSTRACT

Disclosded a solid imaging device and method of fabricating the same for preventing the contamination due to the particles or dust during the dicing and bonding processes by providing a cover glass adhesively attached directly onto the wafer, and for handling the device with ease during and after the dicing processes. The solid imaging device is characterized by the cover means directly formed on the periphery of the solid imaging element. The cover means is optically transparent and physically rigid. The method of fabricating the solid imaging device comprises etching a plate means, wherein the plate means is optically transparent and physically rigid, and eliminating a portion of said plate means corresponding to a pad portion by sandblasting, matching and attaching the boundary of the etched side of the plate means to a periphery of a image sensor on the wafer, dicing the image sensor from the wafer, die bonding the diced image sensor to a ceramic package or PCB, and wire bonding the pad portion of the image sensor to the package or PCB and molding the image sensor. Accordingly, the contamination of the image sensor area due to the wafer particles created during the dicing process and dust from the external environment can be prevented, so that the throughput is improved.

### BACKGROUND OF THE INVENTION

1. Field of the Invention

The present invention relates to a solid imaging device and method of fabricating the same for preventing the contamination due to the particles or dust during the dicing and bonding processes by providing a cover glass bonded directly onto the device wafer, and for handling the solid imaging device with ease.

2. Description of the Prior Art

Recently, the video cameras, particularly portable video cameras having compact size and lightweight for the home appliances have been developed to provide higher functionality. However, the customers' demands for the higher image quality, such as full color reproduction ability or even finer representation of details still exist and become more growing. In order to meet the demands, the relevant technology for a plurality of elements of the video cameras has been remarkably improved. Particularly, the performance of the solid imaging device, called as CCD (Charge Coupled Device), which is the most important element of the video camera, has been significantly improved and the number of CCDs or CMOS equipped in the video camera has been significantly increased.

FIG. 1 illustrates a sectional view of a conventional solid imaging device assembled by a ceramic package that was the main stream in the prior art. In FIG. 1, reference numeral 1 is a ceramic package 1 is provided with a metalized conductor 2 thereon. The ceramic package 1 is provided with a recess 3 in its center portion. Inside the recess 3, the CCD or CMOS 4 is secured by wire bonding with use of a conductive adhesive. The electrode pad 6 of the CCD or CMOS 4 is wire boded to the metalized conductor 2 by the metal wire 7. Reference numeral 8 is a lead terminal welded on the side of the metalize conductor 2 which is exposed in the direction of the external side of the ceramic package 1.

FIG. 2 illustrates a sectional view of another conventional solid imaging device assembled by a resin package. The resin package 12 has an in-molded lead frame 11 comprising inner leads 9 and outer leads 10, and is provided a recess 13 in its center portion. Inside the recess 13, the CCD or CMOS 4 is secured and retained by die bonding with use of a conductive paste 14. The electrode pad 6 on the CCD or CMOS 4 is wire bonded to the inner lead 9 by the metal wire 7.

The steps of fabricating a conventional solid imaging device are illustrated in FIG. 3. Referring to FIG. 3, a wafer that has been subjected to a series of processes for fabricating a plurality of image sensors thereon is carried into a process chamber in step P100.

And, the dicing process is performed on the wafer to separate each of the image sensors from the wafer in step P110. While the dicing process is performed, a ceramic package or PCB is carried into the chamber instep P120. Then, the respective image sensor, so called as a bear chip, diced in step P110 is die bonded to the ceramic package or PCB in step P130. In step P140, the pad 6 of the bear chip is wire bonded to the package or PCB. After the wire bonding process is completed, the package is covered with a cover glass to protect the bear chip and its bondage or interconnection. The cover glass is examined in step P150 for its quality and condition, and cut into a uniform size in step P160.

The sectional view of the solid imaging device accomplished by the aforementioned process steps is shown in FIG. 4. The sectional view of FIG. 4 is the final view after all the process steps shown in FIG. 3 are finished, and it is substantially same with each of the sectional views of the conventional solid imaging devices shown in FIGS. 1 and 2. The only difference of FIG. 4 from FIGS. 1 and 2 lies in the cover glass 15. The cover glass 15 is provided to protect the bear chip. That is, since the bear chip has more than hundreds of thousand sensors, such as photo diodes, for converting an image formed by a lens to electric signals, the contamination of the image sensing area of the sensor due to the dust created in transporting the device causes the poor quality of the product. The cover glass prevents such a contamination.

However, the dust and impurities can also be created due to the wafer particles and debris during the dicing process and die or wire bonding processes as well as in transporting the device. They cause decreases the throughput of the solid imaging device.

### SUMMARY OF THE INVENTION

It is, therefore, an object of the present invention to provide an solid imaging device and method of fabricating the same for preventing the throughput decreases due to the dust and impurities remained in the bear chip, the most important part of the solid imaging device, by bonding a cover glass directly onto the device wafer to prevent the contamination due to the wafer particles and dust during the dicing and bonding processes and to facilitate the handling of the device wafer and the diced individual bear chips.

According to a one aspect of the present invention to achieve the above object, there is provided a solid imaging device comprising a solid imaging element secured in the center portion of a package by die bonding with use of a conductive adhesive, a cover means formed directly on the upper surface of the periphery of a image sensing area of the solid imaging element, wherein the cover means is optically transparent and physically rigid.

According to an additional aspect of the present invention, the cover means is glass, and one side of the glass is etched and the one side of the glass is attached to the periphery of the solid imaging element.

According to an additional aspect of the present invention, the cover means is acrylic or plastic, and one side of the cover means has a recess and the other side is flat, wherein boundary of the recess is attached to the periphery of said solid imaging element.

According to another aspect of the present invention to achieve the above object, there is provided a method of fabricating a solid imaging device comprising etching a plate means, wherein the plate means is optically transparent and physically rigid, and eliminating a portion of said plate means corresponding to a pad portion by sandblasting, matching and attaching the etched side of the plate means onto a periphery of a image sensor on a wafer, dicing the image sensor from the wafer, die bonding the diced image sensor to a ceramic package or PCB, and wire bonding the pad portion of the image sensor to the package or PCB and molding the image sensor.

According to another aspect of the present invention to achieve the above object, there is provided a solid imaging device comprising a solid imaging element secured in the center portion of a package by die bonding with use of a conductive adhesive, a side wall formed directly on the upper surface of the solid imaging element, wherein the side wall has a constant height and surrounds a image sensing area of the solid imaging element, and a cover means formed on the side wall, wherein the cover means is optically transparent and physically rigid.

According to an additional aspect of the present invention, the side wall is acrylic or plastic for being shaped easily, and wherein the side wall is shaped into a rectangular donut configuration.

According to an additional aspect of the present invention, the cover means is selected from a group comprising glass, acrylic and plastic, and each of the both sides of the cover means has a flat face.

According to another aspect of the present invention to achieve the above object, there is provided a solid imaging device comprising forming a supporting means to have a rectangular donut configuration by use of easily shapeable material, adhesively attaching a cover means on a supporting face of the supporting means, wherein the cover means is an optically transparent and physically rigid plate, matching the cover means with a image sensor area on a wafer to attach the supporting means to a periphery of the image sensor, dicing the image sensor from the wafer, die bonding the diced image sensor to a ceramic package or PCB, and wire bonding a pad portion of the image sensor to the package or PCB and molding the image sensor.

According to another aspect of the present invention to achieve the above object, there is provided a solid imaging device comprising a solid imaging element secured in the center portion of a package by die bonding with use of a conductive adhesivem, a side wall formed directly on the upper surface of the solid imaging element, wherein the side wall has a constant height and surrounds a image sensing area of the solid imaging element, and a cover means attached directly on a image sensing area of the solid imaging element by use of a transparent bond, wherein the cover means is optically transparent and physically rigid.

According to another aspect of the present invention to achieve the above object, there is provided a method of fabricating a solid imaging device comprising bonding a plate means onto an upper surface of an image sensor on a wafer by use of a transparent bond, wherein the plate means is a optically transparent and physically rigid, dicing the image sensor to which the plate means is bonded from the wafer, die bonding the diced image sensor to a ceramic package or PCB, and wire bonding a pad portion of the image sensor to the package or PCB and molding the image sensor.

### BRIEF DESCRIPTION OF THE DRAWINGS

The above objects, features and advantages of the present invention will become more apparent from the following detailed description when taken in conjunction with the accompanying drawings, in which:

FIG. 1 is a sectional view of a conventional solid imaging device.

FIG. 2 is a sectional view of another conventional solid imaging device.

FIG. 3 is a flow chart illustrating the steps of fabricating the conventional solid imaging device.

FIG. 4 is a sectional view of the conventional solid imaging device fabricated by the production flow shown in FIG. 3.

FIG. 5 is a flow chart illustrating the steps of fabricating the solid imaging device according to the present invention.

FIG. 6 is a diagram showing the sectional views during the fabrication steps and the final sectional view of the accomplished solid imaging device according to a first embodiment of the present invention.

FIG. 7 is a diagram showing the sectional views during the fabrication steps and the final sectional view of the accomplished solid imaging device according to a second embodiment of the present invention.

FIG. 8 is a sectional view of the solid imaging device according to a third embodiment of the present invention.

FIG. 9 is a flow chart schematically illustrating the steps of fabricating the solid imaging device shown in FIG. 8.

FIG. 10 is a sectional view of the solid imaging device shown in FIG. 7 after completing a molding process.

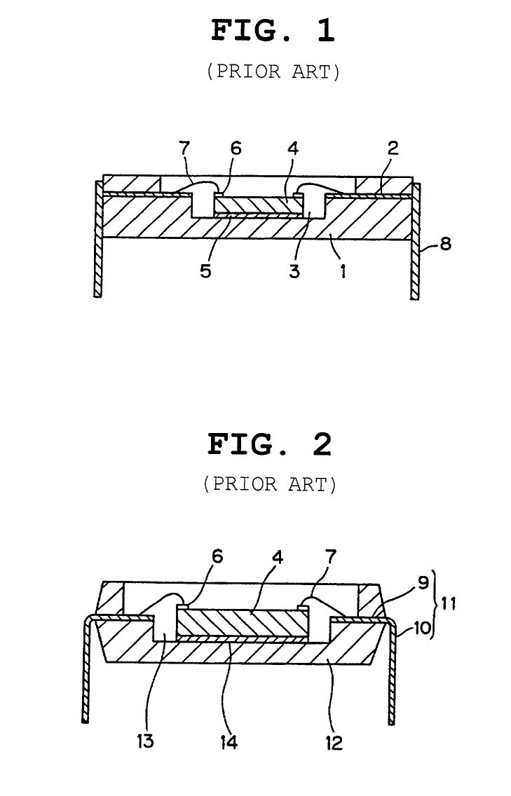

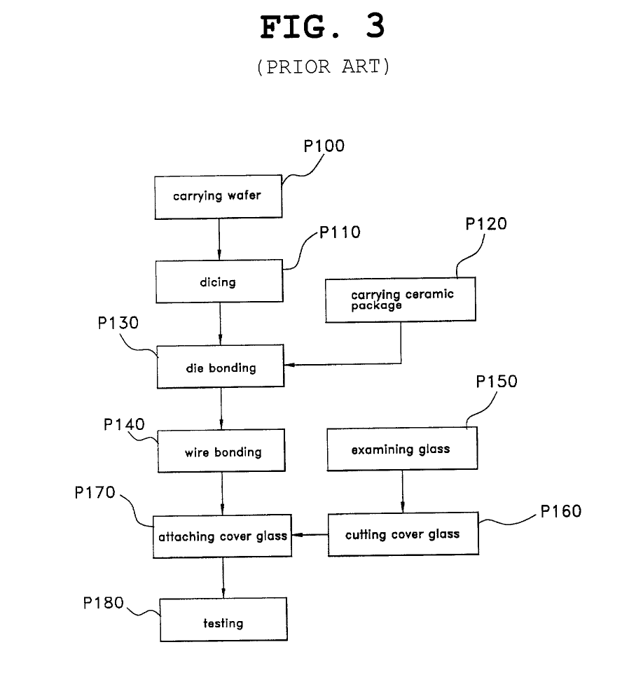

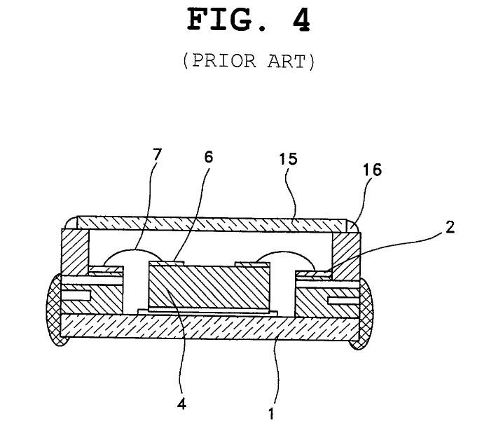

### DETAILED DESCRIPTION OF THE PREFERRED EMBODIMENT

A preferred embodiment of the present invention will now be described with reference to the accompanying drawings. In the following description, same drawing reference numerals are used for the same elements even in different drawings. The matters defined in the description such as a detailed construction and elements of a device are nothing but the ones provided to assist in a comprehensive understanding of the invention. Thus, it is apparent that the present invention can be carried out without those defined matters. Also, well-known functions or constructions are not described in detail since they would obscure the invention in unnecessary detail.

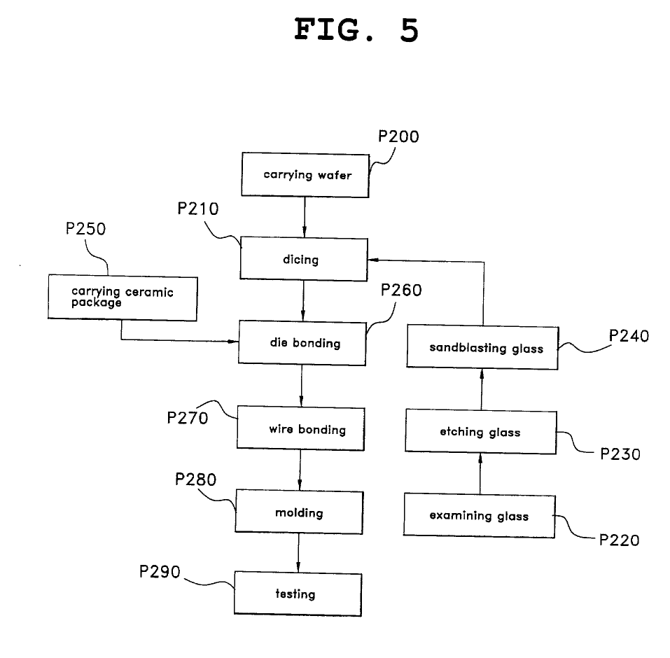

FIG. 5 is a flow chart illustrating the fabrication steps of fabricating the solid imaging device according to the present invention. Referring to FIG. 5, the device wafer on which many image sensors have been made simultaneously is carried into a process chamber in step P200. And, the dicing process is prepared in step P210.

Specifically, at first, in step P210, a cover glass is bonded onto the periphery of the bear chip to protect the bear chip prior to the dicing process. The cover glass is examined for the quality and condition in advance in step P220, and is etched in step P230. The cover glass is further sandblasted in step P240 to eliminate a portion of the cover glass corresponding to a pad portion to be used for wire bonding later.

Then, the dicing process is performed to separate individual bear chips, i.e., image sensors, from the device wafer in step P210. A ceramic package or PCB is carried into the chamber in step P250. The individual chips are bonded to the ceramic package or PCB by die bonding in step of P260. In step P270, the pad portion of the bear chip, which is die bonded onto the package, is wire bonded to the package or PCB. After the wire bonding of step P270 is completed, the molding process is performed in step P280 to mold the solid imaging device. And, the assembled solid image device is tested for the performance in step 290.

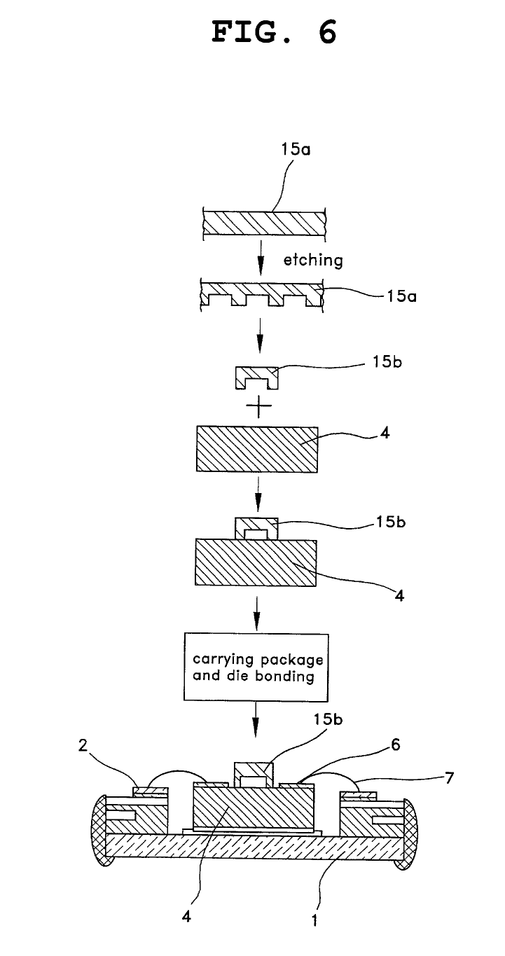

The aforementioned fabrication steps are schematically illustrated in FIG. 6 with several sectional views during the fabrication processes. The final sectional view of the accomplished solid imaging device is also illustrated in FIG. 6.

Referring to FIG. 6, the ceramic package is provided with the metalized conductor 2 on its upper surface and has a recess 3 in its center portion. The bear chip 4 is secured inside the recess 3 by die bonding with use of a conductive adhesive 5. The electrode pad 6 of the bear chip 4 is wire bonded to the metalized conductor 2 by use of the metallic wire 7. The lead terminal 8 is welded on the section of the metalized conductor 2 that is exposed in the direction of the external side of the ceramic package 1.

A single cover means 15b, which is optically transparent and physically rigid, is attached directly onto the periphery of the bear chip 4 to cover the image sensor thereon. The cover means 15b is fabricated by etching the one side of the glass plate 15a to forma concave thereon in step P230. The periphery of the concave of the cover means 15b is matched and secured to the periphery of the bear chip 4 to cover the image sensor.

The cover means 15b is preferably made of glass, but it may be also made of acrylic or plastic.

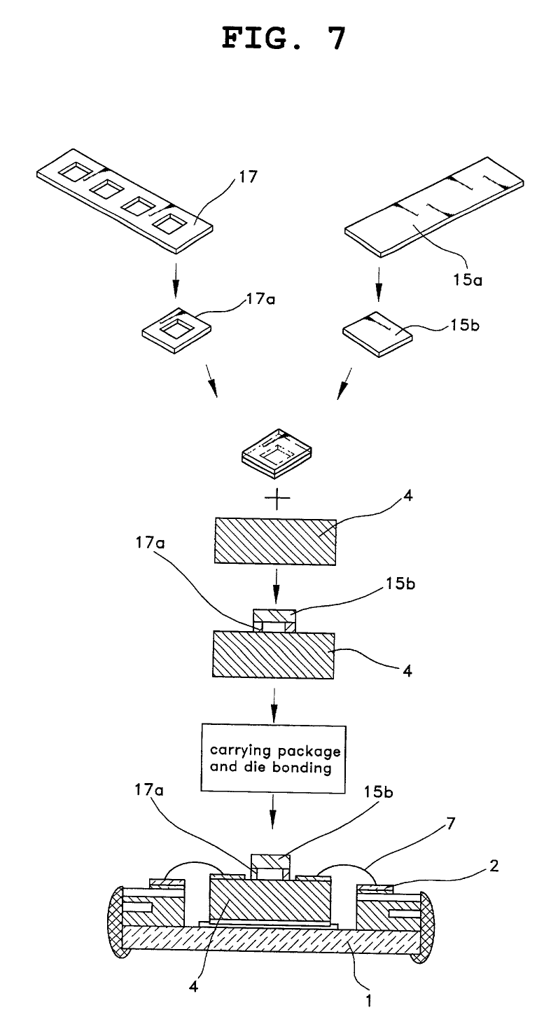

FIG. 7 is a diagram showing sectional views during the fabrication steps and the accomplished solid imaging device according to a second embodiment of the present invention. Referring to FIG. 7, the ceramic package 1 is provided with the metalized conductor 2 on its upper surface, and has a recess 3 in its center portion. The bear chip 4 is secured and retained inside the recess 3 by die bonding with use of a conductive adhesive 5. And, the electrode pad 6 of the bear chip 4 is wire bonded to the metalized conductor 2 by use of the metallic wire 7. The lead terminal 8 is welded on the section of the metalized conductor 2 that is exposed in the direction of the external side of the ceramic package 1.

A side wall 17a having a constant height is formed on the periphery of the upper surface of the bear chip 4. A cover means 15b, which is optically transparent and physically rigid, is attached onto the side wall 17a. The side wall 17a is made of a material being apt to shape easily, such as acrylic or plastic. In the present embodiment, the side wall 17a is made into a rectangular donut structure to support the cover means 15b. That is, the single cover means 15b is attached directly onto the upper face of the side wall 17a.

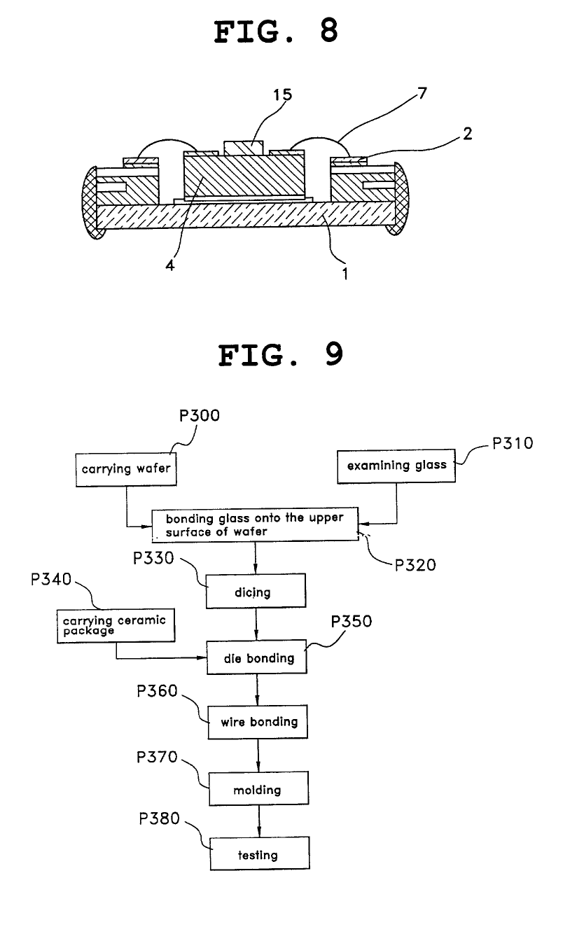

In addition to the aforementioned embodiments, it is also possible that the flat cover means made of glass, acrylic or plastic, etc., which is optically transparent and physically rigid, is bonded directly on to the bear chip 4 by use of a transparent adhesive. The accomplished device accordingly has a sectional structure as shown in FIG. 8.

FIG. 9 is a flow chart illustrating the steps of fabricating the solid imaging device shown in FIG. 8 according to a third embodiment of the present invention. Referring to FIG. 9, the device wafer on which many image sensors have been made simultaneously is carried into the process chamber in step P300. Meanwhile, in step P310, the cover glass is examined for the quality and condition. And, then, the examined glass is bonded onto the upper surface of the device wafer with use of a transparent adhesive in step P320.

Then, the dicing process is performed to separate the individual bear chips, i.e. image sensors, from the wafer in step P330. The ceramic package or PCB is carried into the chamber in step P340. The individual chip is bonded to the ceramic package or PCB by die bonding in step P350. In step P360, the pad portion of the bear chip, which is bonded onto the package earlier, is wire bonded to the package or PCB. After completing the wire bonding in step P360, the molding process is performed in step P370.

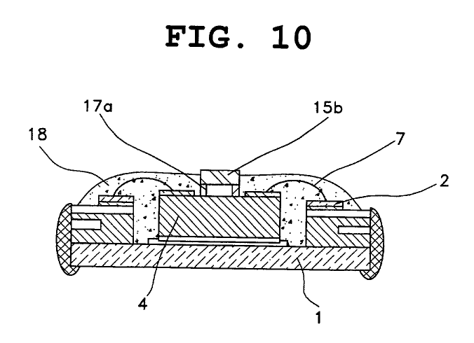

FIG. 10 shows an exemplary result of the molding process applied to the solid imaging device fabricated according to a second embodiment shown in FIG. 7. The reference numeral 18 is an epoxy resin used in the molding process.

By the molding process, the stability of the bonding portion of the metal wire 7 is improved, and the decrease of the throughput due to the impurities remaining in the imaging sensor can be prevented.

According to the solid imaging device and method of fabricating the same of the present invention, the contamination of the image sensor area due to the wafer particles created during the dicing process or the dust created from the external environment can be prevented, so that the throughput is improved.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A solid imaging device comprising,
a solid imaging element secured in the center portion of a package by die bonding with use of a conductive adhesive;
a cover means formed directly on the upper surface of the periphery of a image sensing area of said solid imaging element, wherein the cover means is optically transparent and physically rigid.

2. The device of claim 1, wherein said cover means is glass, and one side of the glass is etched and said one side of the glass is attached to the periphery of said solid imaging element.

3. The device of claim 1, wherein said cover means is acrylic or plastic, and one side of the cover means has a recess and the other side is flat, wherein boundary of the recess is attached to the periphery of said solid imaging element.

4. A method of fabricating a solid imaging device comprising,
the first process of etching a plate means, wherein the plate means is optically transparent and physically rigid, and eliminating a portion of said plate means corresponding to a pad portion by sandblasting;
the second process of matching and attaching the etched side of the plate means onto a periphery of a image sensor on a wafer;
the third process of dicing the image sensor from the wafer;
the fourth process of die bonding the diced image sensor to a ceramic package or PCB; and
the fifth process of wire bonding the pad portion of the image sensor to the package or PCB and molding the image sensor.

5. A solid imaging device comprising,
a solid imaging element secured in the center portion of a package by die bonding with use of a conductive adhesive;
a side wall formed directly on the upper surface of the solid imaging element, wherein the side wall has a constant height and surrounds a image sensing area of the solid imaging element; and
a cover means formed on the side wall, wherein the cover means is optically transparent and physically rigid.

6. The solid imaging device of claim 5, wherein the side wall is acrylic or plastic for being shaped easily, and wherein the side wall is shaped into a rectangular donut configuration.

7. The solid imaging device of claim 5, wherein the cover means is selected from a group comprising glass, acrylic and plastic, and each of the both sides of the cover means has a flat face.

8. The solid imaging device of claim 6, wherein the cover means is selected from a group comprising glass, acrylic and plastic, and each of the both sides of the cover means has a flat face.

9. A method of fabricating a solid imaging device comprising,
the first process of forming a supporting means to have a rectangular donut configuration by use of easily shapeable material;
the second process of adhesively attaching a cover means on a supporting face of the supporting means, wherein the cover means is an optically transparent and physically rigid plate;
the third process of matching the cover means with a image sensor area on a wafer to attach the supporting means to a periphery of the image sensor;
the fourth process of dicing the image sensor from the wafer;
the fifth process of die bonding the diced image sensor to a ceramic package or PCB; and
the sixth process of wire bonding a pad portion of the image sensor to the package or PCB and molding the image sensor.

10. A solid imaging device comprising,
a solid imaging element secured in the center portion of a package by die bonding with use of a conductive adhesive; and
a cover means attached directly on a image sensing area which is formed directly on the upper surface of the solid imaging element by use of a transparent bond, wherein the cover means is optically transparent and physically rigid.

11. A method of fabricating a solid imaging device comprising,
the first process of bonding a plate means onto an upper surface of an image sensor on a wafer by use of a transparent bond, wherein the plate means is a optically transparent and physically rigid;
the second process of dicing the image sensor to which the plate means is bonded from the wafer;
the third process of die bonding the diced image sensor to a ceramic package or PCB; and
the fourth process of wire bonding a pad portion of the image sensor to the package or PCB and molding the image sensor.
